(19) United States
(12) Patent Application Publication
(10) Pub. No.: US 2024/0055260 A1
(43) Pub. Date: Feb. 15, 2024

(54) METHOD FOR MANUFACTURING A SEMICONDUCTOR DEVICE

(71) Applicant: TAIWAN SEMICONDUCTOR MANUFACTURING COMPANY, LTD., Hsinchu (TW)

(72) Inventors: Peng-Soon LIM, Hsinchu (TW); Chung-Liang CHENG, Hsinchu (TW); Huang-Lin CHAO, Hsinchu (TW)

(73) Assignee: TAIWAN SEMICONDUCTOR MANUFACTURING COMPANY, LTD., Hsinchu (TW)

(21) Appl. No.: 17/887,122

(22) Filed: Aug. 12, 2022

(51) Int. Cl. H01L 21/28; H01L 21/02; H01L 21/265

(52) U.S. Cl. CPC H01L 21/28194; H01L 21/0223; H01L 21/265

(57) ABSTRACT

A method for manufacturing a semiconductor device includes: depositing metal sputtered from a metal target on a semiconductor structure having a recess, so as to fill the recess; and oxidizing the metal on the semiconductor structure to turn the metal into dielectric.

### BACKGROUND

The semiconductor integrated circuit (IC) industry has over the past decades experienced tremendous advancements and is still experiencing vigorous development. With the dramatic advances in IC design, to fully fill a recess of a semiconductor device with dielectric to form an isolation in the recess is a big challenge.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are flow charts illustrating a method for manufacturing a semiconductor device in accordance with some embodiments.

FIGS. 3 to 10 illustrate intermediate stages of the method for manufacturing a semiconductor device in accordance with some embodiments, where FIG. 5 is a schematic perspective view, FIGS. 3 and 4 are schematic sectional views similar to a schematic sectional view taken along line A-A of FIG. 5, FIG. 6 is a schematic sectional view taken along line B-B of FIG. 5, and FIGS. 7-10 are schematic sectional views similar to a schematic sectional view taken along line C-C of FIG. 5.

FIG. 11 is a flow chart illustrating a method for manufacturing a semiconductor device in accordance with some embodiments.

FIGS. 12 to 14 illustrate intermediate stages of the method for manufacturing a semiconductor device in accordance with some embodiments, where FIG. 12 is a schematic perspective view. FIG. 13 is a schematic sectional view taken along line D-D of FIG. 12, and FIG. 14 is a schematic sectional view similar to FIG. 13.

FIG. 15 is a flow chart illustrating a method for manufacturing a semiconductor device in accordance with some embodiments.

FIGS. 16 to 24 illustrate intermediate stages of the method for manufacturing a semiconductor device in accordance with some embodiments, where FIGS. 16-20 are schematic perspective views. FIG. 21 is a schematic sectional view taken along line E-E of FIG. 20, and FIGS. 22-24 are schematic sectional views similar to FIG. 21.

FIG. 25 is a flow chart illustrating a method for manufacturing a semiconductor device in accordance with some embodiments.

FIGS. 26 and 27 are schematic perspective views illustrating intermediate stages of the method for manufacturing a semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on.” “above,” “over.” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

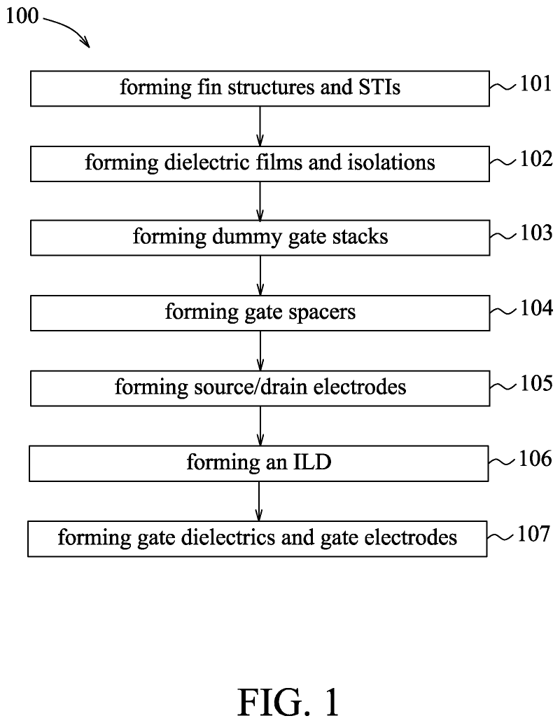

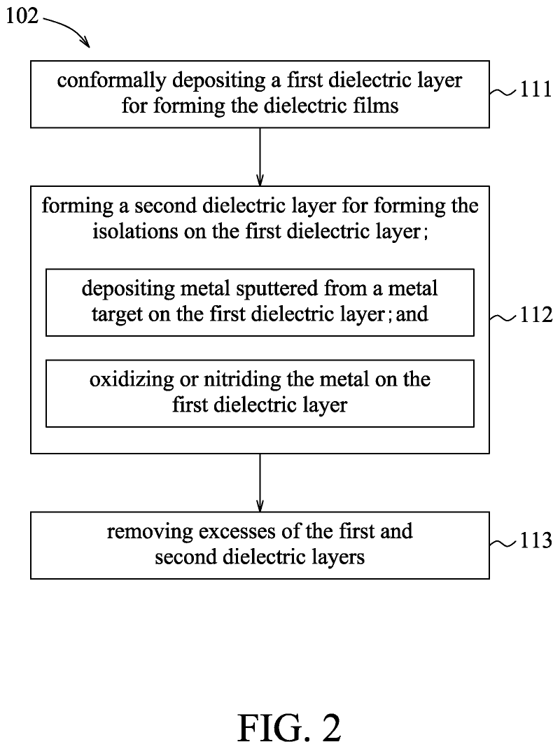

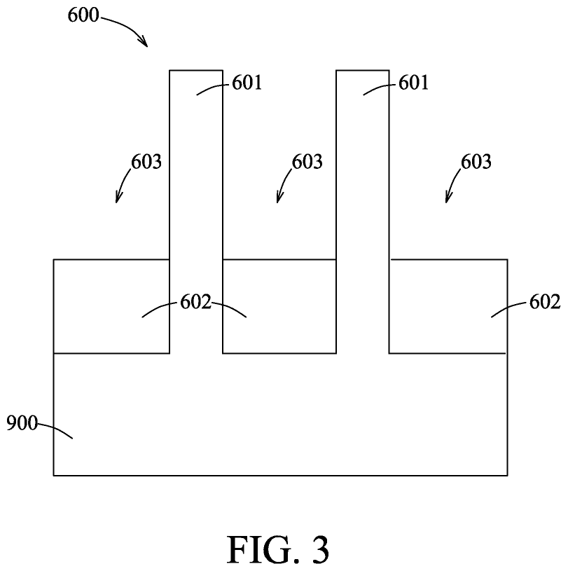

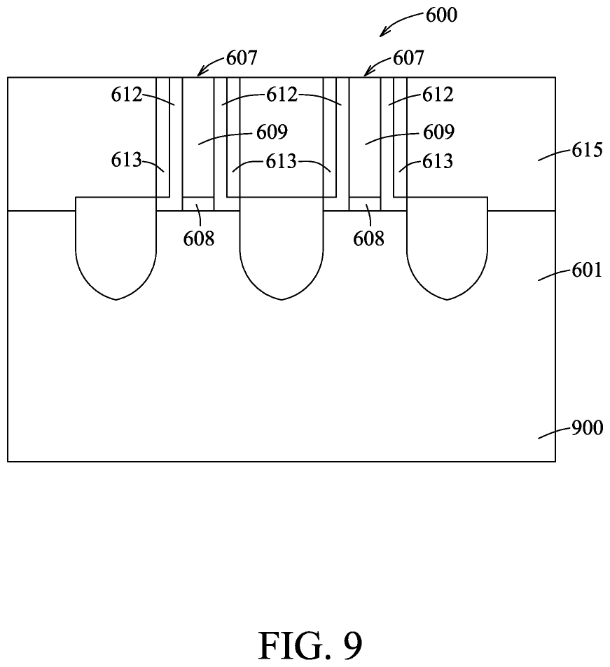

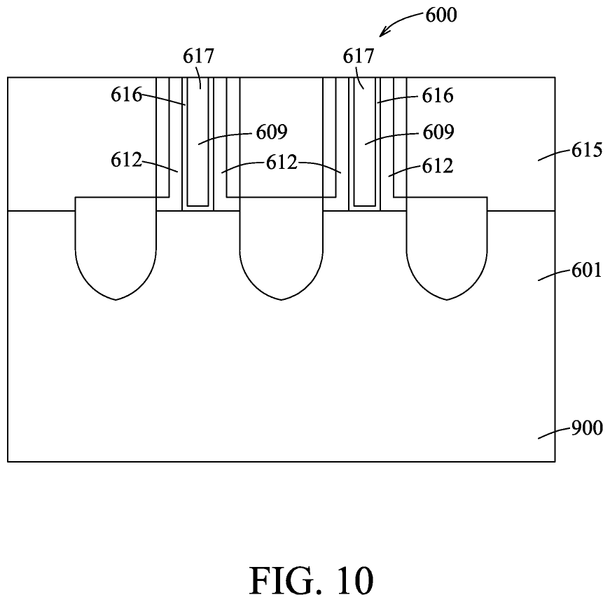

FIGS. 1 and 2 are flow charts illustrating a method 100 for manufacturing a semiconductor device in accordance with some embodiments. The semiconductor device includes a plurality of fin field-effect transistors (FinFETs). FIGS. 3 to 10 are schematic sectional or perspective views of semiconductor structures 600 during various stages of the method 100. The method 100 and the semiconductor structures 600 are collectively described below. However, additional steps can be provided before, after or during the method 100, and some of the steps described herein may be replaced by other steps or be eliminated. Similarly, further additional features may be present in the semiconductor structures 600, and/or features present may be replaced or eliminated in additional embodiments.

Referring to FIGS. 1 and 3, the method 100 begins at step 101, where a substrate 900 is patterned to form a plurality of fin structures 601, and a plurality of shallow trench isolations (STIs) 602 are formed to fill lower portions of a plurality of recesses 603 that define the fin structures 601. In some embodiments, the substrate 900 may be patterned using a photolithography process and an etching process. The photolithography process may include, for example, but not limited to, coating the substrate 900 with a photoresist, soft-baking, exposing the photoresist through a photomask, post-exposure baking, developing the photoresist, and hard-baking, so as to form a patterned photoresist. The etching process may be implemented by etching the substrate 900 through the patterned photoresist using, for example, dry etching, wet etching, reactive ion etching (RIE), atomic layer etching (ALE), other suitable techniques, or combinations thereof. The patterned photoresist may be removed after the etching process. In some embodiments, the STIs 602 may be formed by: (a) depositing a dielectric layer for forming the STIs 602 on the substrate 900 and the fin structures 601 using, for example, chemical vapor deposition (CVD), plasma enhanced chemical vapor deposition (PECVD), physical vapor deposition (PVD), atomic layer deposition (ALD), other suitable techniques, or combinations thereof; (b) removing an excess of the dielectric layer using, for example, chemical mechanical polishing (CMP), or other suitable planarization techniques, so as to expose top surfaces of the fin structures 601; and (c) etching back the dielectric layer using, for example, dry etching, wet etching, RIE. ALE, other suitable techniques, or combinations thereof, so as to form the STIs 602. In some embodiments, the substrate 900 may be a silicon substrate. In some embodiments, the dielectric layer for forming the STIs 602 may include, for example, silicon oxide, silicon nitride, silicon oxynitride, high dielectric constant materials, other suitable materials, or combinations thereof.

Referring to FIGS. 1, 2, 3 and 4, the method 100 then proceeds to step 102, where, with respect to each of the recesses 603, a dielectric film 604 and an isolation 605 are formed to fill an upper portion of the recess 603. The dielectric film 604 is formed between the isolation 605 and the fin structure(s) defined by the recess 603, and between the isolation 605 and the STI 602 in the recess 603. In some embodiments, step 102 may include sub-steps 111-113. In sub-step 111, a first dielectric layer for forming the dielectric films 604 in the recesses 603 is conformally deposited on the fin structures 601 and the STIs 602 using, for example, CVD, ALD, other suitable techniques, or combinations thereof. In sub-step 112, a second dielectric layer for forming the isolations 605 in the recesses 603 is formed on the first dielectric layer by: (a) depositing metal sputtered from a metal target (i.e., sputter source material) on the first dielectric layer to fill remaining segments of the upper portions of the recesses 603; and (b) oxidizing or nitriding the metal on the first dielectric layer to turn the metal into dielectric (i.e., metal oxide or metal nitride) that serves as the second dielectric layer. In sub-step 113, excesses of the first and second dielectric layers are removed using, for example, CMP, or other suitable planarization techniques to expose the top surfaces of the fin structures 601, so as to form the dielectric films 604 and the isolations 605. In some embodiments, the first dielectric layer may include, for example, oxide (e.g., SiO₂), low dielectric constant materials (e.g., SiOCN), nitride (e.g., SiN), other suitable materials, or combinations thereof. In some embodiments, the metal target may include, for example, Hf, Zr, Ti, W, other suitable materials, or combinations thereof. In some embodiments, the metal on the first dielectric layer may be oxidized using reactive oxygen species (for example, but not limited to, IV-O₃ or O-plasma), or may be nitrided using reactive nitrogen species (for example, but not limited to, N₂-plasma or NH₃-plasma). It should be noted that a volume of the metal oxide or the metal nitride would be larger than a volume of the metal (i.e., volume expansion occurs during the oxidation or nitridation process).

In some embodiments, the metal sputtered from the metal target may be mostly ionized using high pressure and/or using RF power and optionally DC power. In addition, the substrate 900 may be biased with a voltage (e.g., via an auto capacitance tuner) while the metal is being sputtered and deposited, so the ionized metal would travel in a direction perpendicular to the substrate 900, thereby improving deposition profile of the metal on the first dielectric layer. Alternatively, the sputtered metal may be collimated to travel in a direction perpendicular to the substrate 900. With the metal traveling perpendicular to the substrate 900, the second dielectric layer can have a high bottom coverage (i.e., a ratio of a thickness of portions of the second dielectric layer in the recesses 603 to a thickness of portions of the second dielectric layer on the fin structures 601) that is typically greater than about 75%, and can have a low overhang (i.e., each of portions of the second dielectric layer that cover sidewalls the fin structures 601 can have a uniform or near uniform thickness).

In some embodiments, the metal is sputtered and deposited under a pressure that falls within a range of from about 50 mTorr to about 400 mTorr, so the sputtered metal can be well ionized, and the sputter deposition process can be fast enough.

In some embodiments, the metal is sputtered and deposited at a temperature that falls within a range of from about 18° C. (i.e., cooling water temperature) to about 450° C. When the temperature is greater than 450° C. junctions of the final semiconductor structure 600 (e.g., P/N junctions) may be affected to result in leakage currents, and metal may react with silicon and nitride in the semiconductor structure 600.

In some embodiments, the metal is oxidized or nitrided at a temperature that falls within a range of from about 18° C. to about 300° C. When the temperature is greater than 300° C. metal may react with silicon in the semiconductor structure 600.

In some embodiments, in sub-step 112, the second dielectric layer may be formed on the first dielectric layer by conformal deposition that uses, for example, CVD, ALD, other suitable techniques, or combinations thereof.

In some embodiments, in sub-step 112, the second dielectric layer may be formed on the first dielectric layer by depositing dielectric reactively sputtered from a metal target on the first dielectric layer.

Referring to FIGS. 1, 5 and 6, the method 100 then proceeds to step 103, where the first dielectric films 604 and the isolations 605 are etched to form a plurality of recesses 606, and a plurality of dummy gate stacks 607 are formed over the fin structures 601 and fill the recesses 606. Each of the dummy gate stacks 607 includes a dummy gate dielectric 608, a dummy gate electrode 609, a polish-stop layer 610 and a hard mask layer 611 that are arranged from bottom to top. In some embodiments, the first dielectric films 604 and the isolations 605 may be etched using, for example, dry etching, wet etching, RIE. ALE, other suitable techniques, or combinations thereof. In some embodiments, the dummy gate stacks 607 may be formed by: (a) depositing a first layer for forming the dummy gate dielectrics 608 of the dummy gate stacks 607, a second layer for forming the dummy gate electrodes 609 of the dummy gate stacks 607, a third layer for forming the polish-stop layers 610 of the dummy gate stacks 607 and a fourth layer for forming the hard mask layers 611 of the dummy gate stacks 607 using, for example, CVD, PECVD, PVD, ALD, other suitable techniques, or combinations thereof; and (b) patterning the first to fourth layers to form the dummy gate dielectrics 608, the dummy gate electrodes 609, the polish-stop layers 610 and the hard mask layers 611 of the dummy gate stacks 607 using a photolithography process and an etching process similar to those used to pattern the substrate 900 in step 101. In some embodiments, the first layer may include, for example, silicon oxide, silicon nitride, silicon oxynitride, high dielectric constant materials, other suitable materials, or combinations thereof. In some embodiments, the second layer may include, for example, polycrystalline silicon, single crystalline silicon, amorphous silicon, other suitable materials, or combinations thereof. In some embodiments, the third layer may include, for example, silicon nitride (e.g., SiN), silicon oxide, other nitrides, other oxides, other suitable materials, or combinations thereof. In some embodiments, the fourth layer may include, for example, silicon nitride, silicon oxide, silicon oxynitride, other suitable materials, or combinations thereof.

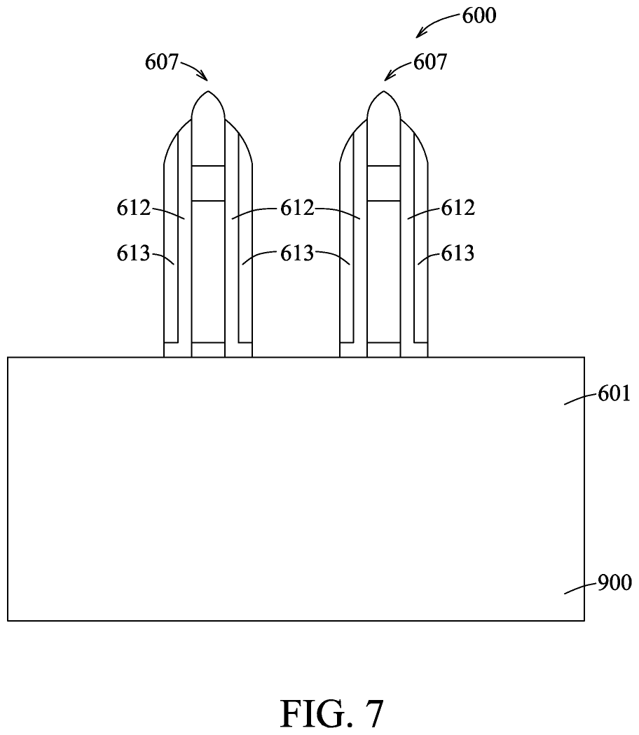

Referring to FIGS. 1 and 7, the method 100 then proceeds to step 104, where a plurality of first gate spacers 612 are respectively formed on sidewalls of the dummy gate stacks 607, and a plurality of second gate spacers 613 are respectively formed on the first gate spacers 612. In some embodiments, the first and second gate spacers 612, 613 may be formed by conformally and sequentially depositing two dielectric layers for forming the first and second gate spacers 612, 613 using, for example, CVD, ALD, other suitable techniques, or combinations thereof, followed by one or more etching processes to selectively leave the first and second spacers 612, 613 remaining on the sidewalls of the dummy gate stacks 607. In some embodiments, the dielectric layer for forming the first gate spacers 612 may include, for example, a silicon-carbon-containing material, a silicon-oxide-containing material, other suitable materials, or combinations thereof. In some embodiments, the dielectric layer for forming the second gate spacers 613 may include, for example, silicon nitride, other suitable materials, or combinations thereof.

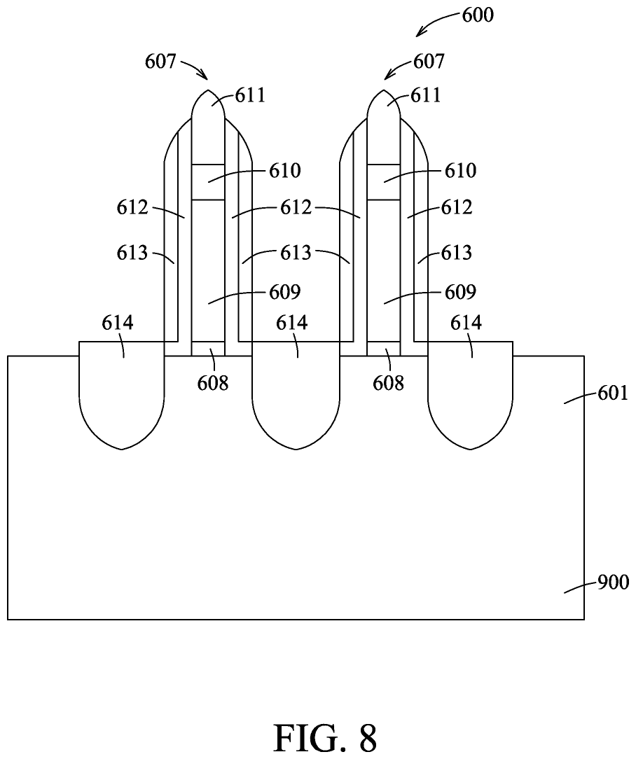

Referring to FIGS. 1 and 8, the method 100 then proceeds to step 105, where a plurality of source/drain electrodes 614 are formed in the fin structures 601 at positions exposed from the dummy gate stacks 607 and the first and second gate spacers 612, 613. In some embodiments, the fin structures 601 may be etched using, for example, dry etching, wet etching, RIE, ALE, other suitable techniques, or combinations thereof, so as to form recesses at the positions exposed from the dummy gate stacks 607 and the first and second gate spacers 612, 613; and the source/drain electrodes 614 may be epitaxially formed in the recesses using, for example, low pressure chemical vapor deposition (LPCVD), other suitable techniques, or combinations thereof. In some embodiments, the source/drain electrodes 614 may include, for example, crystalline silicon (or other suitable materials) doped with an n-type impurity or a p-type impurity.

Referring to FIGS. 1, 8 and 9, the method 100 then proceeds to step 106, where an inter-layer dielectric (ILD) 615 is formed to surround the dummy gate dielectrics 608 and the dummy gate electrodes 609 of the dummy gate stacks 607 that have been covered by the first and second gate spacers 612, 613. In some embodiments, the ILD 615 may be formed by: (a) depositing a dielectric layer for forming the ILD 615 over the structure shown in FIG. 8 using, for example, CVD, PECVD, PVD, ALD, other suitable techniques, or combinations thereof; (b) removing an excess of the dielectric layer, the hard mask layers 611 and the polish-stop layers 610 of the dummy gate stacks 607, and excesses of the first and second gate spacers 612, 613 using, for example, CMP, or other suitable planarization techniques, so as to expose top surfaces of the dummy gate electrodes 609 of the dummy gate stacks 607, thereby forming the ILD 615. In some embodiments, the dielectric layer for forming the ILD 615 may include, for example, silicon oxide, silicon nitride, silicon oxynitride, other suitable materials, or combinations thereof.

Referring to FIGS. 1, 9 and 10, the method 100 then proceeds to step 107, where, with respect to each of the dummy gate stacks 607, the dummy gate electrode 609 and the dummy gate dielectric 608 of the dummy gate stack 607 are removed to form a recess between the corresponding first gate spacers 612, and then a gate dielectric 616 is conformally formed in the recess, and a gate electrode 617 is formed on the gate dielectric 616 in the recess. In some embodiments, the dummy gate electrodes 609 and the dummy gate dielectrics 608 of the dummy gate stacks 607 may be removed using, for example, dry etching, wet etching. RIE, ALE, other suitable techniques, or combinations thereof. In some embodiments, the gate dielectrics 616 and the gate electrodes 617 in the recesses formed from removal of the dummy gate stacks 607 may be formed by: (a) sequentially depositing layers for forming the gate dielectrics 616 and the gate electrodes 617 over the ILD 615 and on inner surfaces of the recesses using, for example, CVD, PECVD, PVD, ALD, other suitable techniques, or combinations thereof, so as to fill the recesses; and (b) removing excesses of the layers using, for example, CMP, or other suitable planarization techniques to expose a top surface of the ILD 615, so as to form the gate dielectrics 616 and the gate electrodes 617. In some embodiments, the layer for forming the gate dielectrics 616 may include, for example, silicon oxide, silicon nitride, silicon oxynitride, high dielectric constant materials, other suitable materials, or combinations thereof. In some embodiments, the layer for forming the gate electrodes 617 may include, for example, titanium, aluminum, tantalum carbide, tantalum carbide nitride, tantalum silicon nitride, tungsten, copper, other suitable materials, or combinations thereof.

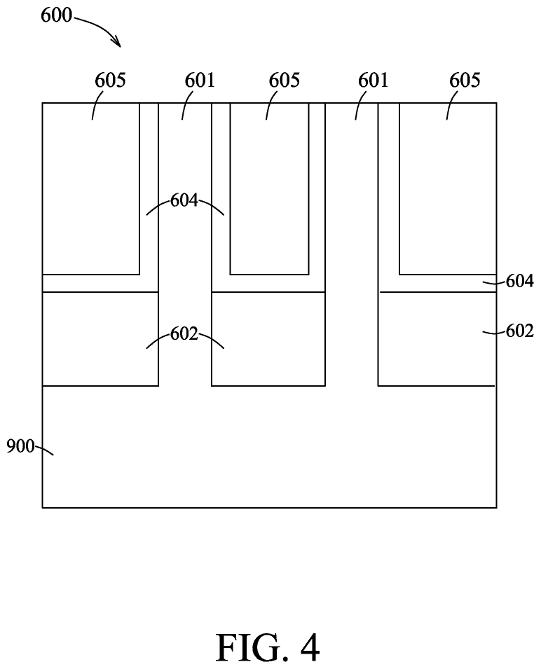

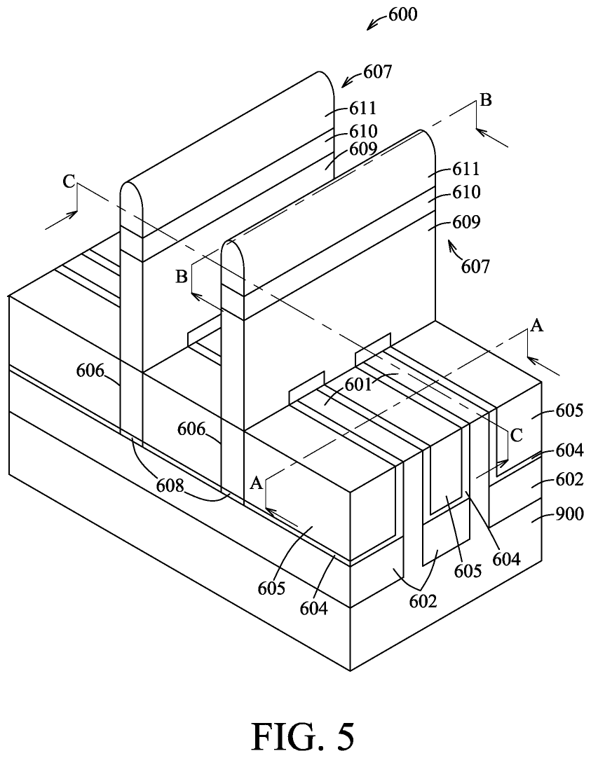

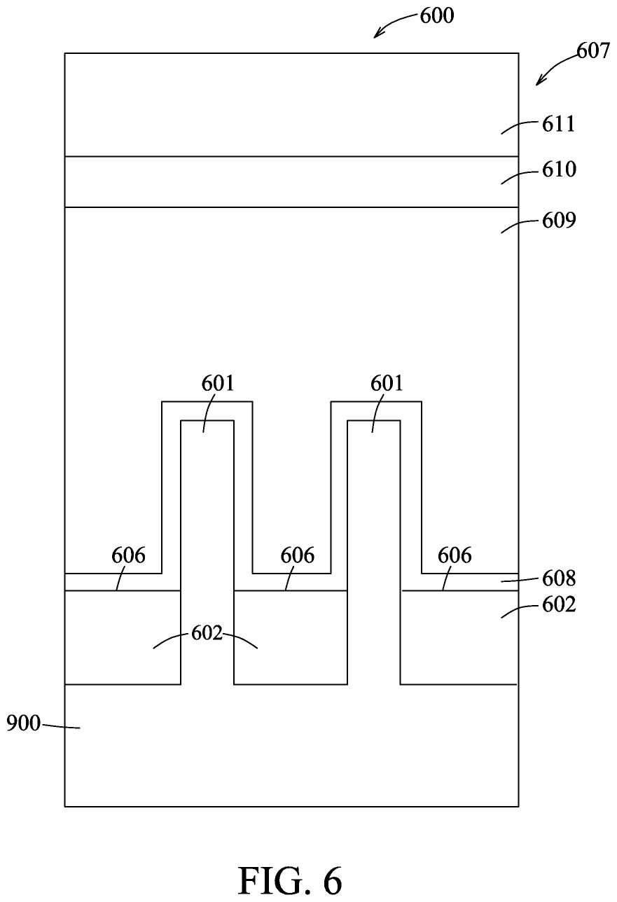

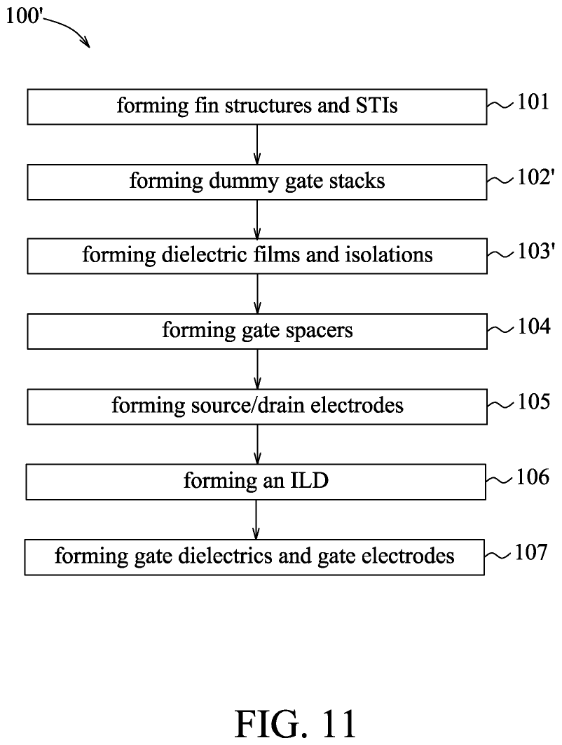

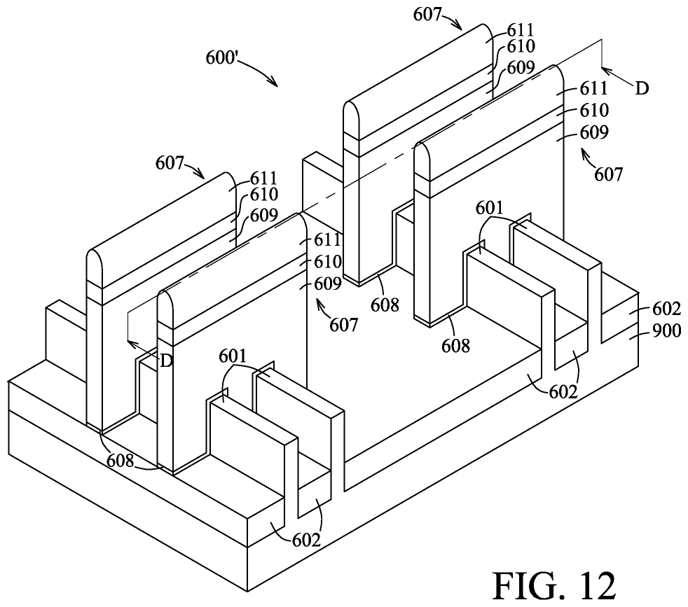

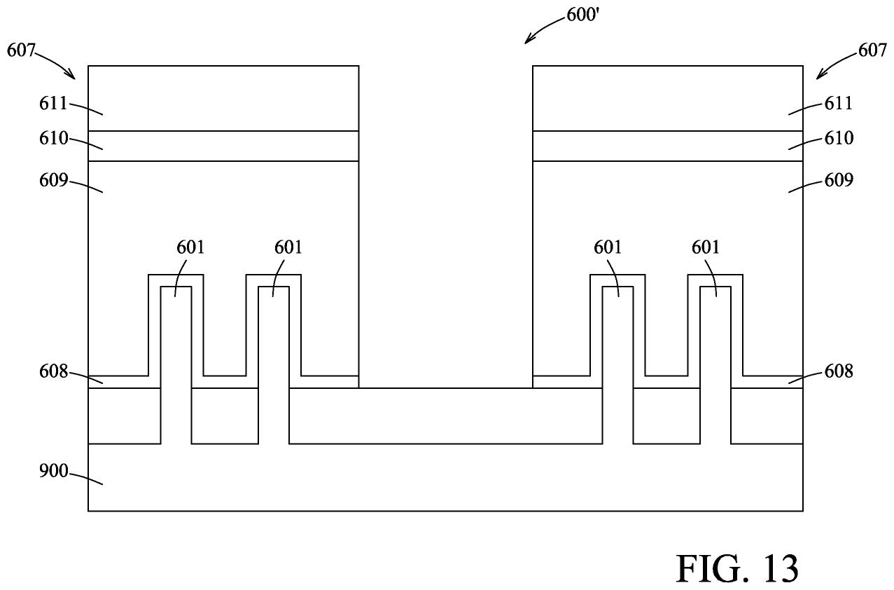

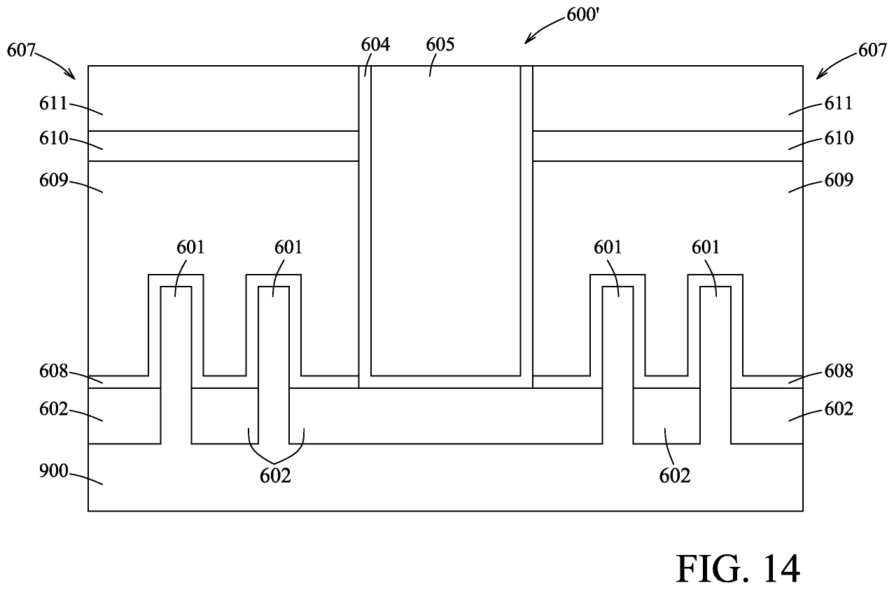

FIG. 11 is a flow chart illustrating a method 100′ for manufacturing a semiconductor device in accordance with some embodiments. FIGS. 12 to 14 are schematic perspective or sectional views of semiconductor structures 600′ during various stages of the method 100′. The method 100′ shown in FIG. 11 is similar to the method 100 shown in FIG. 1, but differs from the method 100 shown in FIG. 1 in steps 102′, 103′. Referring to FIGS. 11, 12 and 13, in step 102′, a plurality of dummy gate stacks 607 are formed over the fin structures 601 and the STIs 602. Each of the dummy gate stacks 607 includes a dummy gate dielectric 608, a dummy gate electrode 609, a polish-stop layer 610 and a hard mask layer 611 that are arranged from bottom to top. The dummy gate stacks 607 may be formed in step 102′ in a way similar to that used to form the dummy gate stacks 607 (see FIGS. 5 and 6) in step 103 of the method 100 (see FIG. 1). Referring to FIGS. 11 and 14, in step 103′, with respect to any two adjacent dummy gate stacks 607 that extend along the same line, a dielectric film 604 and an isolation 605 are formed to fill a space between the two dummy gate stacks 607. The dielectric film 604 is formed between the isolation 605 and each of the two dummy gate stacks 607, and between the isolation 605 and the STI 602. The dielectric film 604 and the isolation 605 in the space between any two adjacent dummy gate stacks 607 may be formed in step 103′ in a way similar to that used to form the dielectric film 604 (see FIG. 4) and the isolation 605 (see FIG. 4) in each recess 603 (see FIG. 3) in step 102 of the method 100 (see FIG. 1).

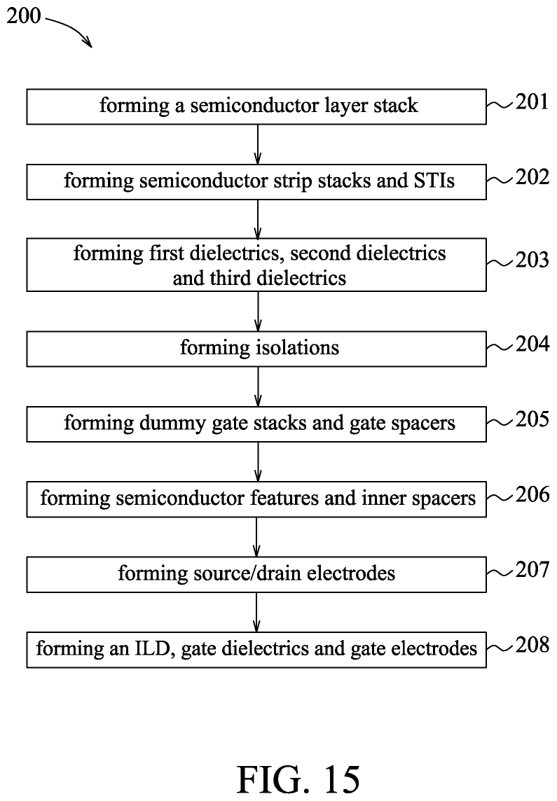

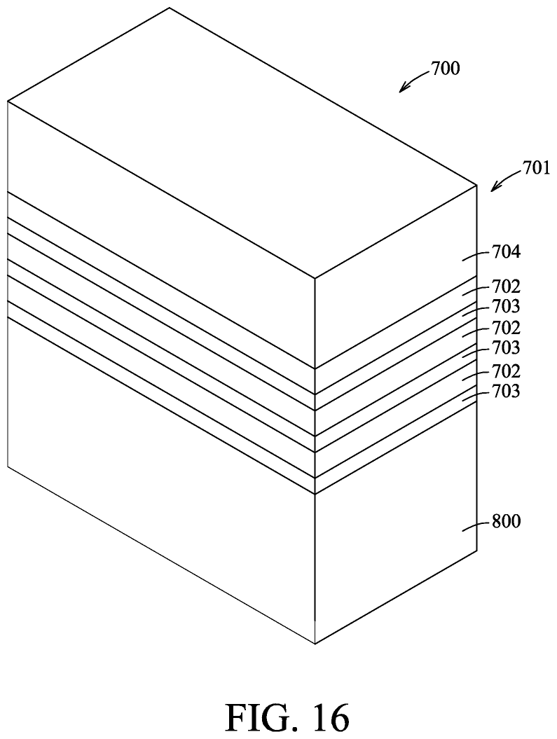

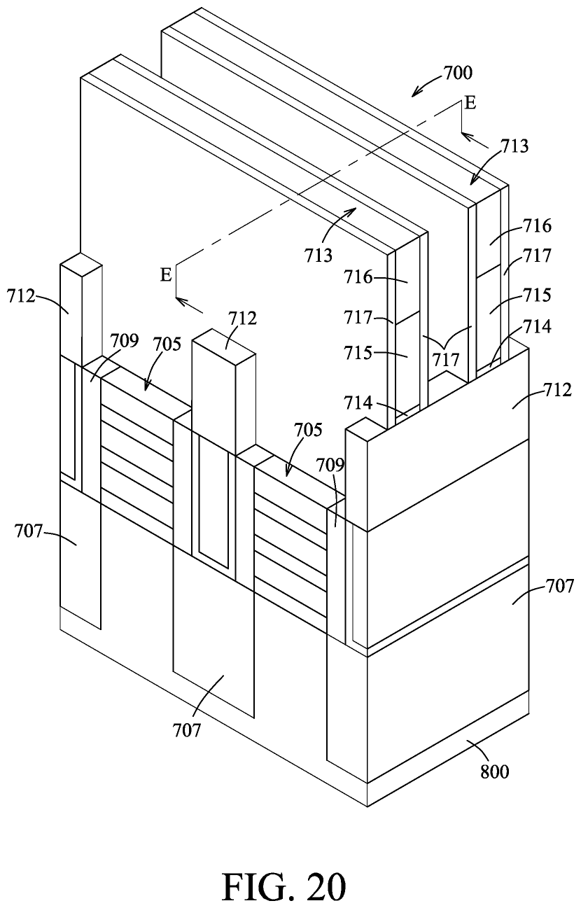

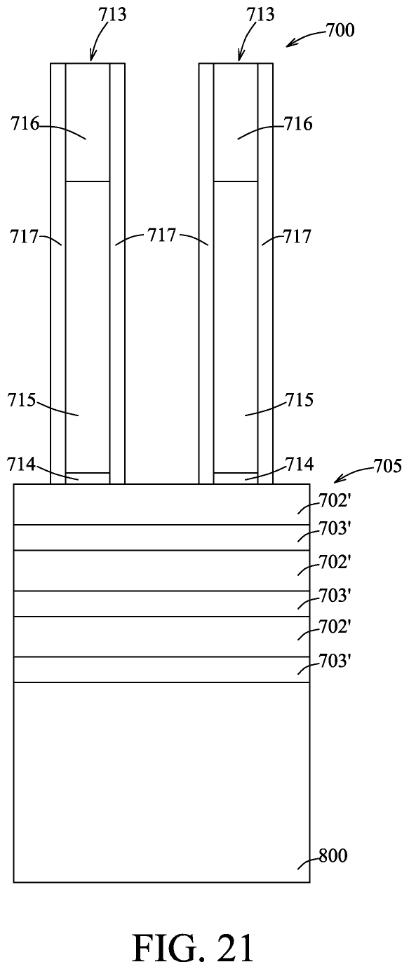

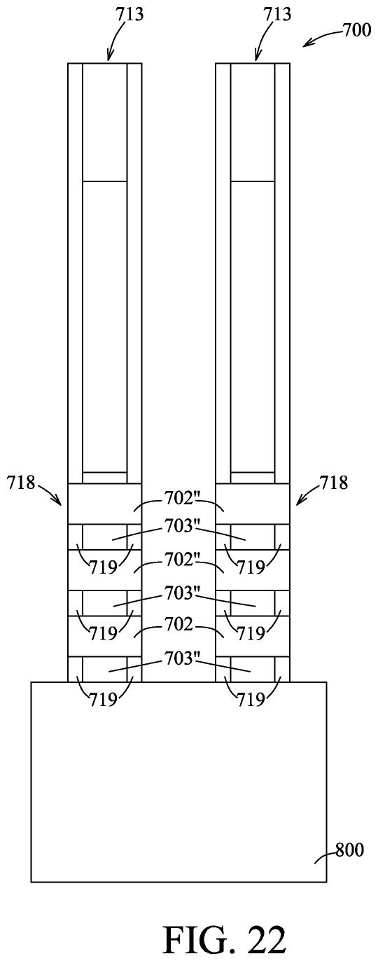

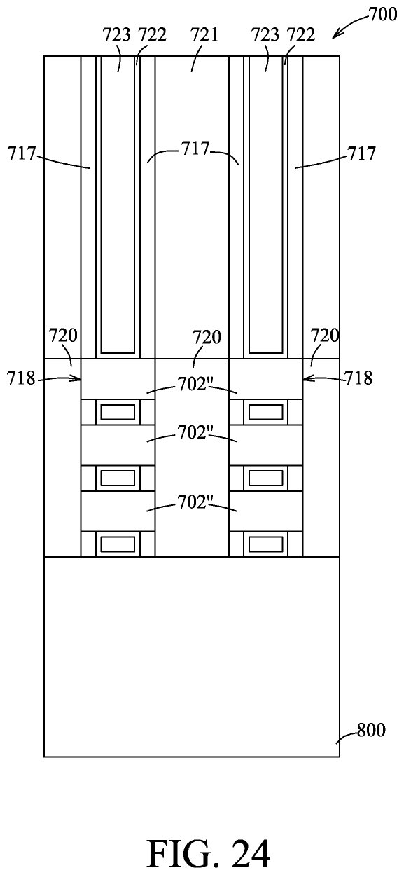

FIG. 15 is a flow chart illustrating a method 200 for manufacturing a semiconductor device in accordance with some embodiments. The semiconductor device includes a plurality of nanosheet FETs. FIGS. 16 to 24 are schematic perspective or sectional views of semiconductor structures 700 during various stages of the method 200. The method 200 and the semiconductor structures 700 are collectively described below. However, additional steps can be provided before, after or during the method 200, and some of the steps described herein may be replaced by other steps or be eliminated. Similarly, further additional features may be present in the semiconductor structures 700, and/or features present may be replaced or eliminated in additional embodiments.

Referring to FIGS. 15 and 16, the method 200 begins at step 201, where a semiconductor layer stack 701 is formed on a substrate 800. The semiconductor layer stack 701 includes a plurality of first semiconductor layers 702 and a plurality of second semiconductor layers 703 stacked in an alternating manner, and a mask layer 704 disposed on an uppermost one of the first and second semiconductor layers 702, 703. In some embodiments, each of the first and second semiconductor layers 702, 703 and the mask layer 704 may be formed using, for example, CVD, PECVD, PVD, ALD, other suitable techniques, or combinations thereof. In some embodiments, the substrate 800 may be a silicon substrate. In some embodiments, the first semiconductor layers 702 may be silicon layers, and the second semiconductor layers 703 may be silicon germanium layers, but the disclosure is not limited in this respect. In some embodiments, the mask layer 704 may include, for example, a nitride (e.g., SiN), an oxide (e.g., SiOₓ), other suitable materials, or combinations thereof.

Referring to FIGS. 15, 16 and 17, the method 200 then proceeds to step 202, where the semiconductor layer stack 701 and the substrate 800 are patterned to form a plurality of semiconductor strip stacks 705, and a plurality of STIs 707 are formed to fill lower portions of a plurality of recesses 708 that define the semiconductor strip stacks 705. Each of the semiconductor strip stacks 705 includes a mask strip 704′ formed from patterning of the mask layer 704, a plurality of first semiconductor strips 702′ formed from patterning of the first semiconductor layers 702, a plurality of second semiconductor strips 703′ formed from patterning of the second semiconductor layers 703, and a substrate strip 706 formed from patterning of the substrate 800. In some embodiments, the semiconductor layer stack 701 and the substrate 800 may be patterned using a photolithography process and an etching process similar to those used to pattern the substrate 900 (see FIG. 3) in step 101 of the method 100 (see FIG. 1). In some embodiments, the STIs 707 may be formed in a way similar to that used to form the STIs 602 (see FIG. 3) in step 101 of the method 100 (see FIG. 1). In some embodiments, the STIs 707 may include, for example, an oxide (e.g., silicon oxide), other suitable materials, or combinations thereof.

Referring to FIGS. 15, 17 and 18, the method 200 then proceeds to step 203, where a plurality of first dielectrics 709 are formed to respectively wrap around portions of the semiconductor strip stacks 705 that are not covered by the STIs 707, and with respect to each of the recesses 708, a second dielectric 710 and a third dielectric 711 are formed to fill a remaining segment of an upper portion of the recess 708. The second dielectric 710 is formed between the third dielectric 711 and each of the first dielectric(s) 709 that wrap(s) around the semiconductor strip stack(s) 705 defined by the recess 708, and between the third dielectric 71 land the STI 707 in the recess 708. In some embodiments, the first dielectrics 709 may be formed using, for example, CVD. PECVD, PVD, ALD, other suitable techniques, or combinations thereof. In some embodiments, the second dielectrics 710 and the third dielectrics 711 in the recesses 708 may be formed by: (a) sequentially depositing layers for forming the second dielectrics 710 and the third dielectrics 711 over the first dielectrics 709 and the STIs 707 using, for example, CVD, PECVD, PVD, ALD, other suitable techniques, or combinations thereof, so as to fill the remaining segments of the upper portions of the recesses 708; and (b) removing excesses of the layers using, for example, CMP, or other suitable planarization techniques to expose top surfaces of the first dielectrics 709, so as to form the second dielectrics 710 and the third dielectrics 711. In some embodiments, the first dielectrics 709 may include, for example, an oxide (e.g., SiO₂), a low dielectric constant material, a nitride (e.g., SiN), other suitable materials, or combinations thereof. In some embodiments, the layer for forming the second dielectrics 710 may include, for example, a silicon-based dielectric material (e.g., silicon oxide, silicon nitride or silicon oxycarbide), other suitable materials, or combinations thereof. In some embodiments, the layer for forming the third dielectrics 711 may include, for example, an oxide (e.g., silicon oxide), other suitable materials, or combinations thereof.

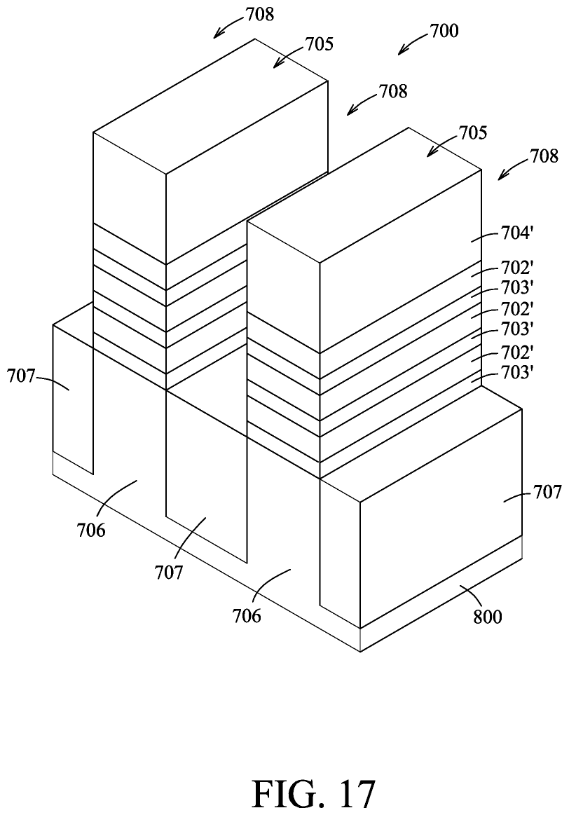

Referring to FIGS. 15, 18 and 19, the method 200 then proceeds to step 204, where the second dielectrics 710 and the third dielectrics 711 are etched back, and isolations 712 are formed to respectively fill portions of the recesses 708 (see FIG. 17) thus released. In some embodiments, the second dielectrics 710 and the third dielectrics 711 are etched back using, for example, dry etching, wet etching, RIE. ALE, other suitable techniques, or combinations thereof. In some embodiments, the isolations 712 may be formed by: (a) depositing a dielectric layer for forming the isolations 712 on the first dielectrics 709, the second dielectrics 710 and the third dielectrics 711 using, for example, CVD, PECVD, PVD, ALD, other suitable techniques, or combinations thereof; and (b) removing excesses of the dielectric layer and the first dielectrics 709 to expose top surfaces of the mask strips 704′ of the semiconductor strip stacks 705, so as form the isolations 712.

Referring to FIGS. 15, 19, 20 and 21, the method 200 then proceeds to step 205, where the mask strips 704′ and portions of the first dielectrics 709 that wrap around the mask strips 704′ are removed to expose a top surface of an uppermost one of the first and second semiconductor strips 702′, 703′ of each of the semiconductor strip stacks 705, and then a plurality of dummy gate stacks 713 are formed over the semiconductor strip stacks 705, the first dielectrics 709 and the isolations 712, and lastly a plurality of gate spacers 717 are respectively formed on sidewalls of the dummy gate stacks 713. Each of the dummy gate stacks 713 includes a dummy gate dielectric 714, a dummy gate electrode 715 and a hard mask layer 716 that are arranged from bottom to top. In some embodiments, the mask strips 704′ and the portions of the first dielectrics 709 that wrap around the mask strips 704′ are removed using, for example, dry etching, wet etching. RIE, ALE, other suitable techniques, or combinations. In some embodiments, the dummy gate stacks 713 may be formed by: (a) depositing a first layer for forming the dummy gate dielectrics 714 of the dummy gate stacks 713, a second layer for forming the dummy gate electrodes 715 of the dummy gate stacks 713, and a third layer for forming the hard mask layers 716 of the dummy gate stacks 713 using, for example, CVD, PECVD, PVD, ALD, other suitable techniques, or combinations thereof; and (b) patterning the first to third layers to form the dummy gate dielectrics 714, the dummy gate electrodes 715 and the hard mask layers 716 using a photolithography process and an etching process similar to those used to pattern the substrate 900 (see FIG. 3) in step 101 of the method 100 (see FIG. 1). In some embodiments, the gate spacers 717 may be formed by conformally depositing a dielectric layer for forming the gate spacers 717 using, for example, CVD, ALD, other suitable techniques, or combinations thereof, followed by one or more etching processes to selectively leave the gate spacers 717 remaining on the sidewalls of the dummy gate stacks 713. In some embodiments, the first layer may include, for example, silicon oxide, other suitable dielectric materials, or combinations thereof. In some embodiments, the second layer may include, for example, polycrystalline silicon, microcrystal silicon, amorphous silicon, other suitable materials, or combinations thereof. In some embodiments, the third layer may include, silicon nitride, silicon oxide, silicon oxynitride, other suitable materials, or combinations thereof. In some embodiments, the dielectric layer may include, for example, a silicon carbon-containing dielectric material, a silicon oxide-containing material, silicon nitride, other suitable materials, or combinations thereof.

Referring to FIGS. 15, 21 and 22, the method 200 then proceeds to step 206, where the first and second semiconductor strips 702′, 703′ of the semiconductor strip stacks 705 are patterned to form a plurality of semiconductor features 718, each of which includes a plurality of first semiconductor elements 702″ formed from patterning of the first semiconductor strips 702′ of a corresponding semiconductor strip stack 705, and a plurality of second semiconductor elements 703″ formed from patterning of the second semiconductor strips 703′ of the corresponding semiconductor strip stack 705; the second semiconductor elements 703″ of the semiconductor features 718 are etched to form recesses at side portions thereof; and inner spacers 719 are formed to fill the recesses. In some embodiments, the first and second semiconductor strips 702′, 703′ may be patterned using a photolithography process and an etching process similar to those used to pattern the substrate 900 (see FIG. 3) in step 101 of the method 100 (see FIG. 1). In some embodiments, the second semiconductor elements 703″ may be etched using, for example, dry etching, wet etching, RIE, ALE, other suitable techniques, or combinations thereof. In some embodiments, the inner spacers 719 may include, for example, silicon (e.g., silicon oxide), carbon (e.g., silicon carbide), oxygen (e.g., silicon oxynitride), nitrogen (e.g., silicon nitride), fluorine, boron, other suitable dielectric materials, or combinations thereof.

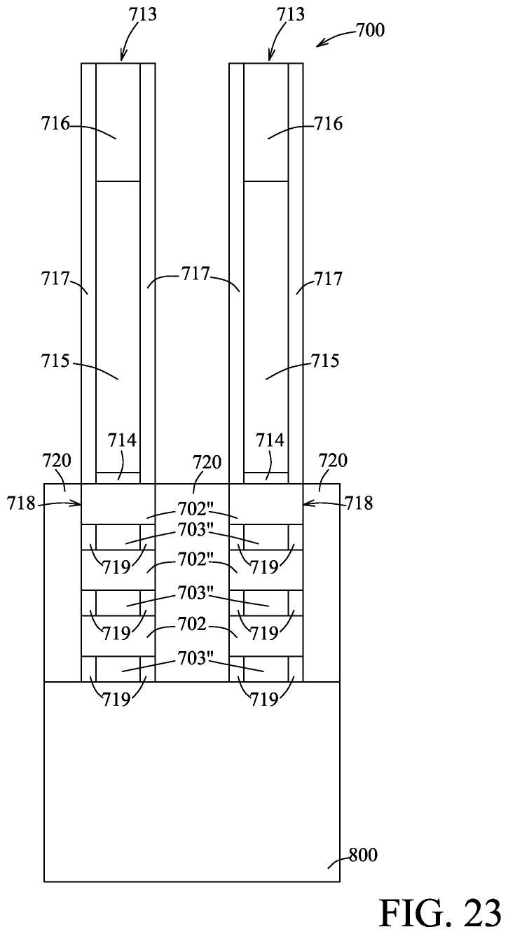

Referring to FIGS. 15 and 23, the method 200 then proceeds to step 207, where a plurality of source/drain electrodes 720 are formed to respectively fill a plurality of recesses defining the combined structure of the semiconductor features 718 and the inner spacers 719. In some embodiments, the source/drain electrodes 720 may be epitaxially formed using, for example, LPCVD, other suitable techniques, or combinations thereof. In some embodiments, the source/drain electrodes 720 may include, for example, crystalline silicon (or other suitable materials) doped with an n-type impurity or a p-type impurity.

Referring to FIGS. 15, 23 and 24, the method 200 then proceeds to step 208, where an ILD 721 is formed to surround the dummy gate electrodes 715 and the dummy gate dielectrics 714 of the dummy gate stacks 713 that have been covered by the gate spacers 717; and with respect to each of the dummy gate stacks 713, the dummy gate electrode 715 and the dummy gate dielectric 714 of the dummy gate stack 713 and the second semiconductor elements 703″ of the semiconductor features 718 right below the dummy gate stacks 713 are removed, and a gate dielectric 722 is formed on the first semiconductor elements 702″ of the semiconductor features 718 thus exposed, and then a gate electrode 723 is formed to surround the first semiconductor elements 702″ that have been covered by the gate dielectric 722. In some embodiments, the ILD 721 may be formed by: (a) depositing a dielectric layer for forming the ILD 721 over the structure shown in FIG. 23 using, for example, CVD, PECVD, PVD, ALD, other suitable techniques, or combinations thereof; (b) removing an excess of the dielectric layer, the hard mask layers 716 of the dummy gate stacks 713, and portions of the gate spacers 717 that cover the hard mask layers 716 using, for example, CMP, or other suitable planarization techniques, so as to expose top surfaces of the dummy gate electrodes 715 of the dummy gate stacks 713, thereby forming the ILD 721. In some embodiments, the dummy gate electrodes 715 and the dummy gate dielectrics 714 of the dummy gate stacks 713 and the second semiconductor elements 703″ of the semiconductor features 718 may be removed using, for example, drying etching, wet etching, RIE. ALE, other suitable techniques, or combinations thereof. In some embodiments, the gate dielectrics 722 and the gate electrodes 723 surrounding the first semiconductor elements 702″ of the semiconductor features 718 may be formed using, for example, PVD. CVD, ALD, other suitable techniques, or combinations thereof. In some embodiments, the dielectric layer for forming the ILD 721 may include, for example, silicon oxide, silicon nitride, SiON, phosphosilicate glass (PSG), borophosphosilicate glass (BPSG), spin-on glass (SOG), fluorosilicate glass (FSG), carbon-doped silicon oxide (e.g., SiCOH), xerogel, aerogel, parylene, divinylsiloxane-bis-benzocyclobutene-based (BCB-based) dielectric material, polyimide, other suitable material, or combinations thereof. In some embodiments, the gate dielectrics 722 may include, for example, Hf-based dielectric materials, Zr-based dielectric materials. Al-based dielectric materials, Ti-based dielectric materials, Ba-based dielectric materials, RE element-based dielectric materials, nitrides, other suitable high dielectric constant materials, or combinations thereof. In some embodiments, the gate electrodes 723 may include, for example, a metal (e.g., copper, aluminum, titanium, tantalum, cobalt, tungsten, or the like, or alloys thereof), polysilicon, metal-containing nitrides (e.g., TaN), metal-containing silicides (e.g., NiSi), metal-containing carbides (e.g., TaC), other suitable conductive materials, or combinations thereof.

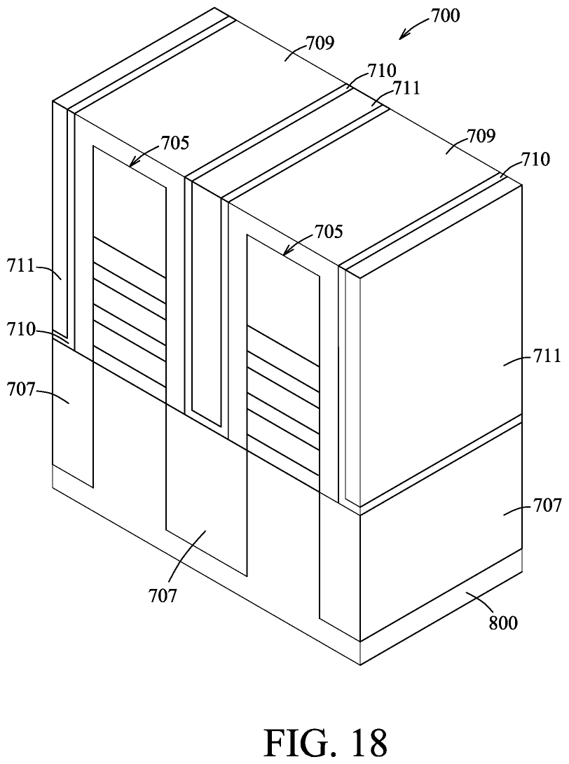

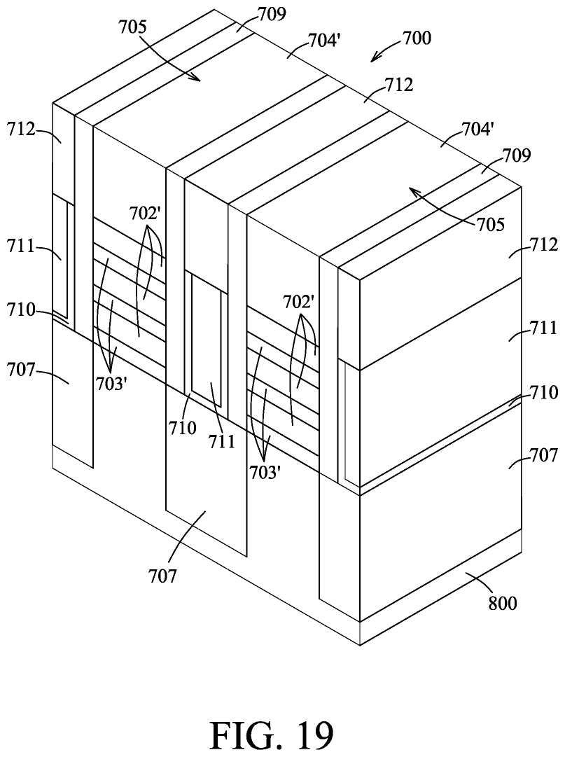

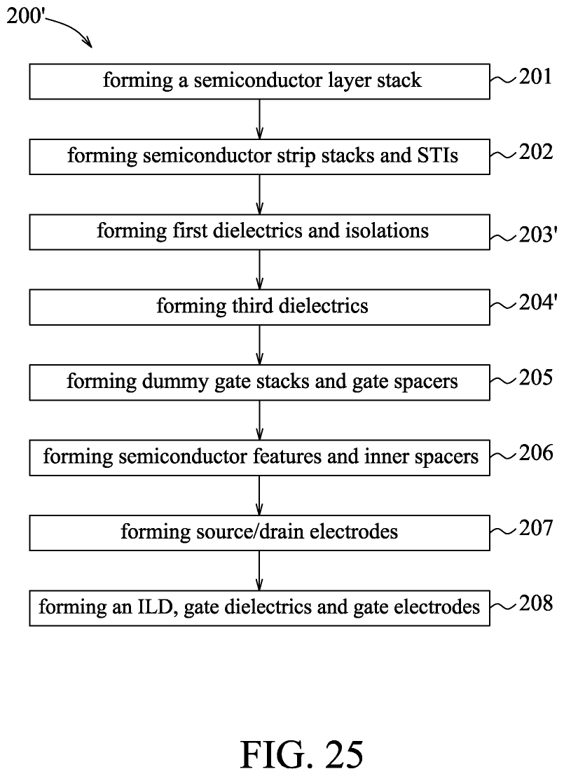

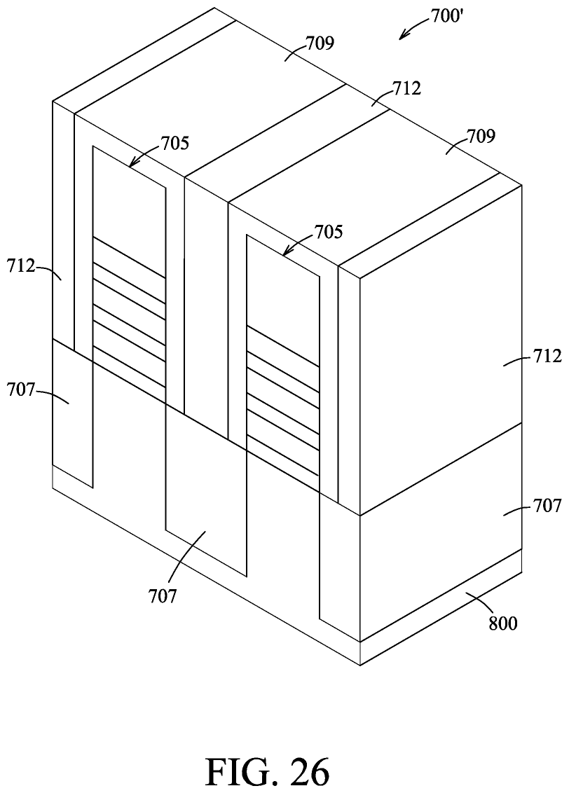

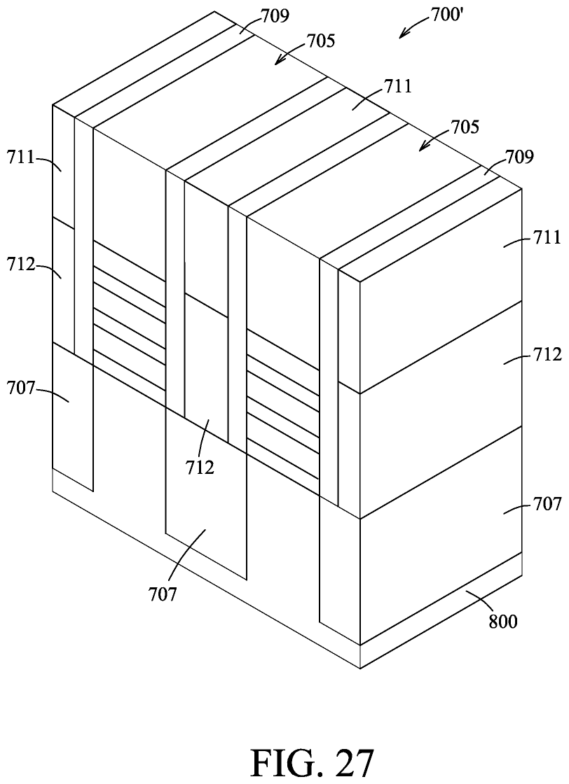

FIG. 25 is a flow chart illustrating a method 200′ for manufacturing a semiconductor device in accordance with some embodiments. FIGS. 26 and 27 are schematic perspective views of semiconductor structures 700′ during various stages of the method 200′. The method 200′ shown in FIG. 25 is similar to the method 200 shown in FIG. 15, but differs from the method 200 shown in FIG. 15 in steps 203′. 204′. Referring to FIGS. 17, 25 and 26, in step 203′, a plurality of first dielectrics 709 are formed to wrap around portions of the semiconductor strip stacks 705 that are not covered by the STIs 707, and a plurality of isolations 712 are formed to respectively fill remaining segments of upper portions of the recesses 708. In some embodiments, the first dielectrics 709 may be formed in step 203′ in a way similar to that used to form the first dielectrics 709 (see FIG. 18) in step 203 of the method 200 (see FIG. 15). In some embodiments, the isolations 712 may be formed in step 203′ in a way similar to that used to form the isolations 712 (see FIG. 19) in step 204 of the method 200 (see FIG. 15). Referring to FIGS. 25, 26 and 27, in step 204′, the isolations 712 are etched back, and a plurality of third dielectrics 711 are formed to respectively fill spaces thus released. In some embodiments, the third dielectrics 711 may be formed by: (a) depositing a dielectric layer for forming the third dielectrics 711 on the first dielectrics 709 and the isolations 712 using, for example, CVD, PECVD, PVD, ALD, other suitable techniques, or combinations thereof, so as to fill the spaces released from etching back of the isolations 712, and (b) removing excesses of the dielectric layer and the first dielectrics 709 to expose top surfaces of the dummy gate structures 705, so as to form the third dielectrics 711.

It should be noted that, in some embodiments, each recess may be a trench that has a long and narrow shape, or a via that has a round or oval shape.

In some embodiments, by depositing the metal sputtered from the metal target to fill the recesses and then oxidizing or nitriding the metal thus deposited to turn the metal into dielectric, it is possible to create a seamless dielectric fill in each recess. In addition, a traveling direction of the sputtered metal can be properly controlled, thereby achieving good recess filling capability.

In accordance with some embodiments of the present disclosure, a method for manufacturing a semiconductor device includes: depositing metal sputtered from a metal target on a semiconductor structure having a recess, so as to fill the recess; and oxidizing the metal on the semiconductor structure to turn the metal into dielectric.

In accordance with some embodiments of the present disclosure, the metal sputtered from the metal target is ionized.

In accordance with some embodiments of the present disclosure, the semiconductor structure is biased with a voltage while the metal is being sputtered and deposited.

In accordance with some embodiments of the present disclosure, the metal sputtered from the metal target is collimated to travel in a direction perpendicular to the semiconductor structure.

In accordance with some embodiments of the present disclosure, the metal is sputtered and deposited under a pressure that falls within a range of from 50 mTorr to 400 mTorr.

In accordance with some embodiments of the present disclosure, the metal is sputtered and deposited at a temperature that falls within a range of from 18° C. to 450° C.

In accordance with some embodiments of the present disclosure, the metal on the semiconductor structure is oxidized using reactive oxygen species.

In accordance with some embodiments of the present disclosure, the metal on the semiconductor structure is oxidized at a temperature that falls within a range of from 18° C. to 300° C.

In accordance with some embodiments of the present disclosure, a method for manufacturing a semiconductor device includes: depositing metal sputtered from a metal target on a semiconductor structure having a recess, so as to fill the recess; and nitriding the metal on the semiconductor device to turn the metal into dielectric.

In accordance with some embodiments of the present disclosure, the metal sputtered from the metal target is ionized.

In accordance with some embodiments of the present disclosure, the semiconductor structure is biased with a voltage while the metal is being sputtered and deposited.

In accordance with some embodiments of the present disclosure, the metal sputtered from the metal target is collimated to travel in a direction perpendicular to the semiconductor structure.

In accordance with some embodiments of the present disclosure, the metal is sputtered and deposited under a pressure that falls within a range of from 50 mTorr to 400 mTorr.

In accordance with some embodiments of the present disclosure, the metal is sputtered and deposited at a temperature that falls within a range of from 18° C. to 450° C.

In accordance with some embodiments of the present disclosure, the metal on the semiconductor device is nitrided using reactive nitrogen species.

In accordance with some embodiments of the present disclosure, the metal on the semiconductor device is nitrided at a temperature that falls within a range of from 18° C. to 300° C.

In accordance with some embodiments of the present disclosure, a method for manufacturing a semiconductor device includes: depositing metal sputtered from a metal target over a semiconductor structure; and performing a chemical reaction on the metal over the semiconductor structure to turn the metal into dielectric.

In accordance with some embodiments of the present disclosure, the chemical reaction includes oxidation.

In accordance with some embodiments of the present disclosure, the chemical reaction includes nitridation.

In accordance with some embodiments of the present disclosure, the metal sputtered from the metal target is ionized.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
depositing metal sputtered from a metal target on a semiconductor structure having a recess, so as to fill the recess; and
oxidizing the metal on the semiconductor structure to turn the metal into dielectric.

2. The method according to claim 1, wherein the metal sputtered from the metal target is ionized.

3. The method according to claim 1, wherein the semiconductor structure is biased with a voltage while the metal is being sputtered and deposited.

4. The method according to claim 1, wherein the metal sputtered from the metal target is collimated to travel in a direction perpendicular to the semiconductor structure.

5. The method according to claim 1, wherein the metal is sputtered and deposited under a pressure that falls within a range of from 50 mTorr to 400 mTorr.

6. The method according to claim 1, wherein the metal is sputtered and deposited at a temperature that falls within a range of from 18° C. to 450° C.

7. The method according to claim 1, wherein the metal on the semiconductor structure is oxidized using reactive oxygen species.

8. The method according to claim 1, wherein the metal on the semiconductor structure is oxidized at a temperature that falls within a range of from 18° C. to 300° C.

9. A method for manufacturing a semiconductor device, comprising:
depositing metal sputtered from a metal target on a semiconductor structure having a recess, so as to fill the recess; and
nitriding the metal on the semiconductor device to turn the metal into dielectric.

10. The method according to claim 9, wherein the metal sputtered from the metal target is ionized.

11. The method according to claim 9, wherein the semiconductor structure is biased with a voltage while the metal is being sputtered and deposited.

12. The method according to claim 9, wherein the metal sputtered from the metal target is collimated to travel in a direction perpendicular to the semiconductor structure.

13. The method according to claim 9, wherein the metal is sputtered and deposited under a pressure that falls within a range of from 50 mTorr to 400 mTorr.

14. The method according to claim 9, wherein the metal is sputtered and deposited at a temperature that falls within a range of from 18° C. to 450° C.

15. The method according to claim 9, wherein the metal on the semiconductor device is nitrided using reactive nitrogen species.

16. The method according to claim 9, wherein the metal on the semiconductor device is nitrided at a temperature that falls within a range of from 18° C. to 300° C.

17. A method for manufacturing a semiconductor device, comprising:
depositing metal sputtered from a metal target over a semiconductor structure; and
performing a chemical reaction on the metal over the semiconductor structure to turn the metal into dielectric.

18. The method according to claim 17, wherein the chemical reaction includes oxidation.

19. The method according to claim 17, wherein the chemical reaction includes nitridation.

20. The method according to claim 17, wherein the metal sputtered from the metal target is ionized.
